(19) United States
(12) Patent Application Publication
(10) Pub. No.: US 2008/0291760 A1
(43) Pub. Date: Nov. 27, 2008

(54) Sub-array architecture memory devices and related systems and methods

(75) Inventors: Koichiro Ito, Ibaraki (JP); Takuya Nakanishi, Ibaraki (JP)

Correspondence Address: TRASK BRITT, P.C./ MICRON TECHNOLOGY, P.O. BOX 2550, SALT LAKE CITY, UT, 84110, US

(73) Assignee: Micron Technology, Inc.

(21) Appl. No.: 11/805,750

(22) Filed: May 23, 2007

(51) Int. Cl. G11C 7/00

(52) U.S. Cl. 365/200

(57) ABSTRACT

Memory devices, systems and methods implementing an architecture for partitioning a memory area of normally used memory cells and redundant memory cells are disclosed. A memory area is partitioned into a plurality of substantially equally sized sub-arrays of normally used memory cells and redundant memory cells. The groups of memory cells in a first portion of the sub-arrays are each selectable by a first quantity of select signals and a second portion of the sub-arrays are each selectable by a second quantity of select signals. One of the plurality of sub-arrays partially includes all of the groups of the redundant memory cells selectable by respective redundant select signals.

### FIELD OF THE INVENTION

Embodiments of the present invention relate generally to the field of memory devices and, more particularly, to redundancy methodologies and sub-array partitioning for memory devices.

### BACKGROUND

A semiconductor memory device typically includes an array of memory cells, and the array is normally partitioned (e.g., divided) into a number of sub-arrays. Memory cells in the array are selected for reading and writing by means of row and column address signals input to the memory device. The row and column address signals are processed by address decoding circuitry to select row lines and column lines in the array to access the desired memory cell or memory cells.

When semiconductor devices are manufactured, defective memory cells may occur in the memory array or in a sub-array. To salvage the semiconductor memory device despite these defective memory cells, and thus to increase overall yield in the manufacturing process, redundancy is commonly implemented. Redundant memory elements are located in the memory array and the memory array will typically have associated with it a plurality of redundant memory elements. When a defective memory cell is detected in the array, redundant decoding circuitry associated with the redundant memory elements may be programmed to respond to the address of the defective memory cell. When the address of the defective memory cell is input to the array, the redundant memory element will respond in place of the defective memory cell.

As noted above, memory cells in a memory array may be partitioned into sub-arrays (e.g., smaller groupings) for improved design, performance and testing. Partitioning of the memory array into a plurality of sub-arrays and associating redundant memory cells therewith presents performance and design tradeoffs. Specifically, various designs for associating redundant memory cells with sub-arrays may result in significant loading of word lines, thus causing a decrease in normal performance of the memory device. Therefore, there is a need to partition the memory array into sub-arrays in a manner such that when the redundant memory cells are included, there is no significant impact on the performance of the memory device.

For the reasons stated above, and for other reasons which will become apparent to those skilled in the art upon reading and understanding the present specification, there is a need in the art for, for example, an approach to partitioning memory cells into sub-arrays such that the inclusion of redundant memory cells does not significantly adversely affect the performance of the memory device.

### BRIEF DESCRIPTION OF THE SEVERAL VIEWS OF THE DRAWINGS

FIG. 1 illustrates partitioning of a memory area, in accordance with an embodiment of the present invention.

FIG. 2 illustrates an embodiment of specific partitioning of memory area into various sub-arrays according to the present invention.

FIG. 3 illustrates another embodiment of specific partitioning of memory area into various sub-arrays according to the present invention.

FIG. 4 illustrates a further embodiment of specific partitioning of memory area into various sub-arrays according to the invention.

FIG. 5 illustrates yet another embodiment of specific partitioning of memory area into various sub-arrays according to the invention.

FIG. 6 illustrates a memory device including one of the various partitionings of sub-arrays, in accordance with various embodiments of the present invention.

FIG. 7 illustrates an electronic system including a memory device, in accordance with the various embodiments of the present invention.

### DETAILED DESCRIPTION

Memory devices may include an array of memory cells that are variously partitioned for functionality and manufacturability. It is known that the manufacture of an entire array of memory cells regularly results in some defective (e.g., lesser performing) memory cells across the array. Rather than scrapping the memory device, redundant memory cells may be co-manufactured on the device and substituted for defective memory cells during operation of the memory array.

The array of memory cells may also be partitioned into sub-arrays which may result in increased manufacturability and performance. By partitioning the memory array into sub-arrays, the quantity of memory cells that coexist on specific signaling lines is reduced, resulting in a reduction in the electrical loading of the signal lines. This may allow for faster signal transitions and therefore an improvement to overall execution performance of the memory device.

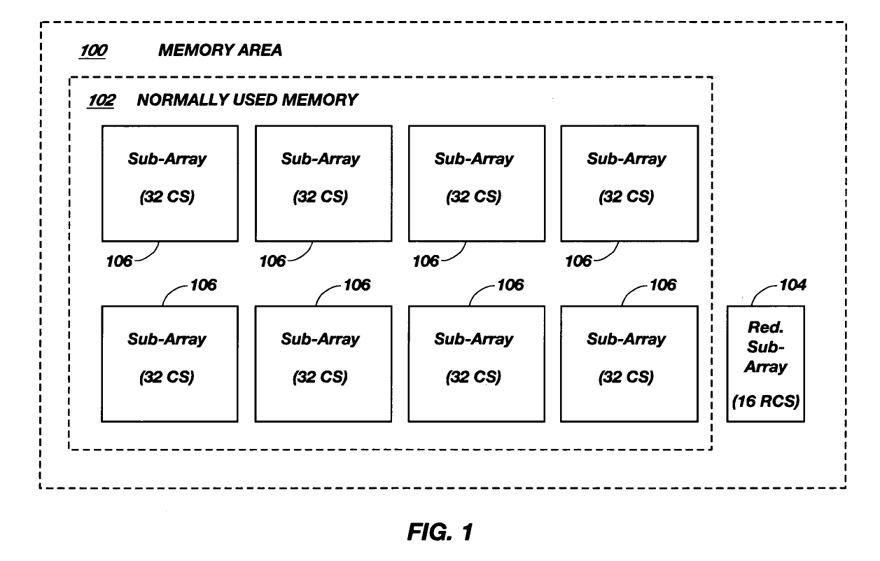

FIG. 1 is a block diagram of a memory area 100 including a normally used memory 102 and a redundant memory 104. As used herein, the term “normally used” with reference to memory, cell groups and cells is merely indicative of memory, cell groups and cells that would be used, if not defective (e.g., underperforming or nonfunctional) and is not otherwise limiting as to function. The normally used memory 102 is partitioned into various sub-arrays 106. Sub-arrays may be partitioned according to a determined quantity of columns, rows, columns and rows, select signals or other partitionable characteristics. By way of example and not limitation, in an illustrative embodiment, the sub-arrays are partitioned in relation to a quantity of column select (CS) signals which are further described below. In general, CS signals result from a partial decoding of the column addresses directed to the normally used memory. When redundancy techniques are utilized, column addresses of defective normally used memory cells are identified, resulting in the decoding of column addresses of redundant memory cells. Similar to the partitioning of the normally used memory cells into sub-arrays in relation to a quantity of column select (CS) signals, a quantity of groups of redundant memory cells are provided in relation to a quantity of Redundant Column Select (RCS) signals.

By way of example and not limitation, the normally used memory 102 is partitioned into eight sub-arrays 106 with each of the sub-arrays 106 including groups of memory cells that are accessible by thirty-two column select (CS) signals. Similarly, the redundant memory 104 includes groups of redundant memory cells that are accessible by sixteen redundant column select (RCS) signals. The specific quantity of column select (CS) signals for each sub-array and redundant column select (RCS) signals for the redundant memory 104 can be based upon desired design guidelines such as the desired size of the normally used memory and the resulting functionality of the memory device following processing and testing.

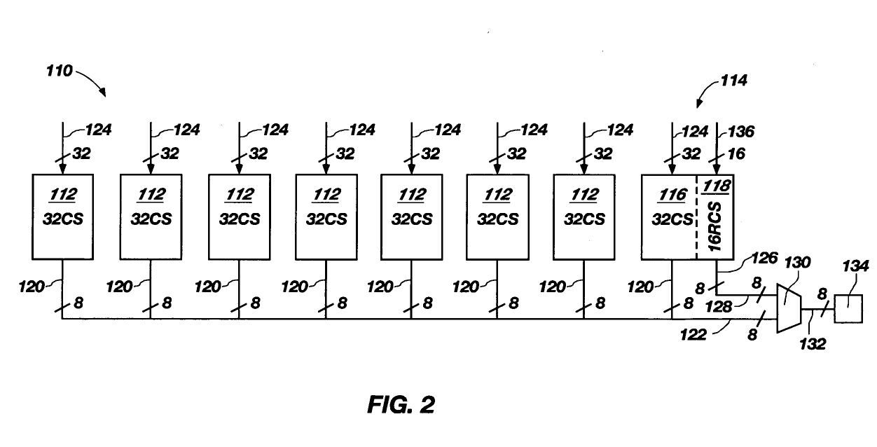

FIG. 2 is a block diagram of an embodiment of specific partitioning of a memory area 110. By way or example and not limitation, the normally used memory is accessible by two hundred fifty-six CS signals with each CS signal configured to activate eight sense amplifiers within the sub-array. The normally used memory is partitioned into seven, for example, similarly sized sub-arrays 112 each including respective groupings of memory cells accessible according to thirty-two CS signals. An eighth, for example, similarly sized group 116 of normally used memory cells is also partitioned. In order to provide the redundancy capability described above, the redundant memory is formed into a group 118 including redundant memory cells accessible according to sixteen, for example, RCS signals. The normally used memory cells group 116 is combined with the redundant memory cells group 118 to form an eighth sub-array 114.

Each of the normally used memory cell sub-arrays 112 and the normally used memory cells of group 116 couples via I/O lines 120 to a Local Input/Output (LIO) line 122 for reading or writing data to specific memory cells within one of the sub-arrays 112 or the group 116 when a respective CS signal 124 is activated. Similarly, the group 118 of the redundant memory cells couples via redundant I/O lines 126 to a Redundant Local Input/Output (RLIO) line 128 (being the same line as line 126 in the present example) for reading or writing data to specific memory cells within one of the redundant memory cell group 118 when a respective RCS signal 136 is activated. The LIO lines 122 and RLIO lines 128 couple to logic 130 for selectively multiplexing data between LIO line 122 and the DQ 134 via an external I/O line 132 when the normally used memory cells are selected. When the redundant memory cells are selected, the logic 130 selectively multiplexes data between RLIO line 128 and the DQ 134 via an external I/O 132.

In the illustrated memory area architecture embodiment, separation of the LIO lines and the RLIO lines is simplified because the addressing distance from the normally used memory space to the redundant memory space is a single address. Furthermore, the normally used memory area is contiguous in a single group while the redundant memory cell group 118 is also contiguous in a single group. Contiguous grouping of related memory cells should result in an improved repair efficiency. Additionally, writing a stress test pattern to the memory area should be simplified because the boundary between the normally used memory and the redundant memory is a single memory address.

It is noted that word lines (not shown) that traverse the sub-arrays for activating the memory cells in the sub-arrays exhibit a load (e.g., a capacitance) that is based on the quantity of memory cells connected to the word line across the sub-array. Accordingly, the word lines that traverse sub-array 114 will be subjected to a greater load due to the increased quantity of memory cells along the word line and thereby exhibit slower performance when compared with one of the sub-arrays 112.

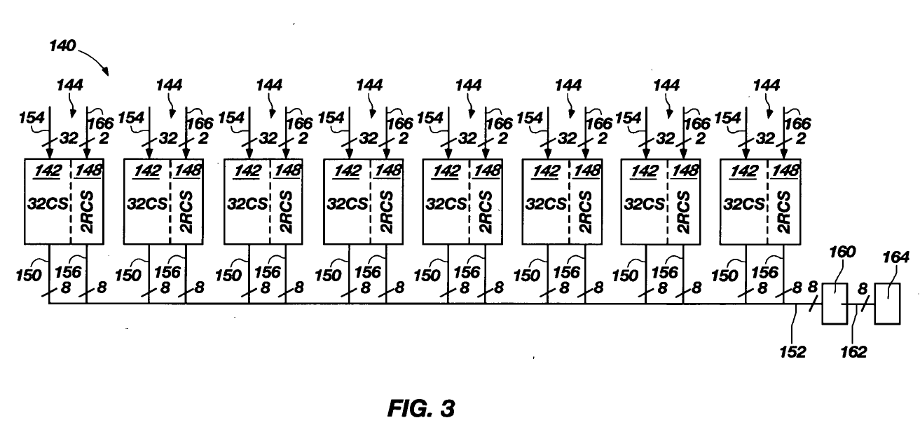

FIG. 3 is block diagram of an embodiment of specific partitioning of a memory area 140. By way of example and not limitation, the normally used memory is accessible by two hundred fifty-six CS signals. The normally used memory is partitioned into eight similarly sized normally used memory cell groups 142, each accessible by thirty-two CS signals 154. A redundant memory is partitioned into eight similarly sized redundant memory cell groups 148, each accessible by two RCS signals 166. The combination of each group 142 and group 148 forms a sub-array, resulting in eight equal size sub-arrays 144.

In each of the sub-arrays 144, the normally used memory cell group 142 couples via local I/O lines 150 to a Common Input/Output (CIO) line 152 for reading or writing data to specific memory cells within one of the normally used memory cell group 142 when a respective CS signal 154 is activated. Similarly, the redundant memory cell group 148 couples via redundant I/O lines 156 to the CLIO line 152 for reading or writing data to specific memory cells within one of the redundant memory cell groups 148 when a respective RCS signal 166 is activated. The CLIO lines 152 couple to logic 160. Logic 160 buffers and selects between local I/O lines 150 and redundant I/O lines 156 for connecting to DQ 164 via an 1,0 line 162.

In the present memory area architecture embodiment having CLIO lines, separation of the local I/O lines 150 and the redundant I/O lines 156 is more involved as the groups of normally used memory cells and the groups of redundant memory cells are intermingled resulting in increased logic for separating the normal and redundant data causing an increased size and a reduction in redundancy efficiency. Furthermore, since the normally used and redundant memory areas are distributed across the various sub-arrays, separately writing a stress test pattern to the normally used memory and the redundant memory is complicated because of the several boundaries between the normally used memory and the redundant memory.

As stated, the word lines (not shown) that traverse the sub-arrays for activating the memory cells exhibit a load that is based on the quantity of memory cells along the word line spanning the sub-array. Accordingly, the word lines that traverse sub-arrays 144 will desirably exhibit an equal load due to the similar lengths of the word lines across the various sub-arrays 144.

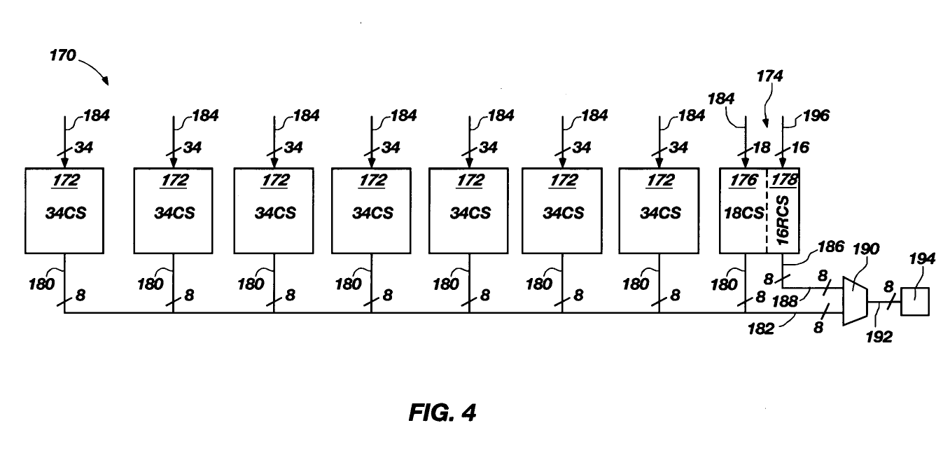

FIG. 4 is a block diagram of an embodiment of specific partitioning of a memory area 170. By way of example and not limitation, the normally used memory is accessible by two hundred fifty-six CS signals. Accordingly, the normally used memory is partitioned into seven, for example, similarly sized sub-arrays 172 each including groups of memory cells accessible according to thirty-two CS signals plus two additional CS signals for a total of thirty-four CS signals per sub-array. An eighth, for example, differently sized group 176 of normally used memory cells is also partitioned and includes a quantity of memory cells accessible by sixteen CS signals. In order to provide the redundancy capability described above, a redundant memory cell group 178 is accessible according to sixteen, for example, RCS signals. The redundant memory cell group 178 is combined with the normally used memory cell group 176 to form an eighth sub-array 174, that is similar in size to each of sub-arrays 172.

Each of the sub-arrays 172 and the normally used memory cell group 176 couples via I/O lines 180 to a Local Input/Output (LIO) line 182 for reading or writing data to specific memory cells within one of the sub-arrays 172 or the normally used memory cell group 176 when a respective CS signal 184 is activated. Similarly, the redundant memory cell group 178 couples via redundant I/O lines 186 to a Redundant Local Input/Output (RLIO) line 188 (same line as line 186 in the present example) for reading or writing data to specific memory cells within the redundant memory cell group 178 when a respective RCS signal 196 is activated. The LIO lines 182 and RLIO lines 188 couple to logic 190 for selectively multiplexing data between LIO line 182 and DQ 194 via an external I/O 192 when the normally used memory cells are selected. When the redundant memory cells are selected, the logic 190 selectively multiplexes data between RLIO line 188 and DQ 194 via the external I/O 192.

In the illustrated memory area architecture embodiment, separation of the LIO lines and the RLIO lines are simplified because the addressing distance from the normally used memory space to the redundant memory space is a single address. Furthermore, the normally used memory area is contiguous in a single group and the redundant memory cell group 178 is also contiguous in a single group, which should result in an improved repair efficiency. Additionally, writing a stress test pattern to the memory area is simplified because the boundary between the normally used memory and the redundant memory is a single memory address.

As stated, the word lines (not shown) that traverse the sub-arrays for activating the memory cells in the sub-arrays exhibit a load that is based on the quantity of memory cells connected to the word line across the sub-array. Accordingly, the word lines that traverse sub-array 174, which includes the redundant memory cell group 178, exhibits a substantially equivalent word line load when compared with the word lines that traverse sub-arrays 172 since each of the sub-arrays 172, 174 are configured to have an equivalent quantity of memory cells in each array as accessed by an equivalent quantity of CS signals 184 or CS signals 184 combined with RCS signals 196. In the present embodiment, the quantity of thirty-four of either CS signals 184 or CS signals 184 and RCS signals 196 are illustrated for each of the sub-arrays 172, 174. Since each of the sub-arrays 172, 174 are substantially equivalent in size, the performance, namely the read and write access times for the word lines, will be substantially equivalent which is in contrast to the different performance of the sub-array 114 having forty eight CS signals 124 and RCS signals 136 of FIG. 2.

Additionally, each of the sub-arrays 172, 174 may be similarly designed as a common sub-array since the sub-array 174 including the redundant memory cell group includes the same quantity of CS signals (CS signals 184 and RCS signals 196) as the CS signals 184 of sub-arrays 172. Accordingly, design and process defects may exhibit more uniformity across the entire memory area of a memory device.

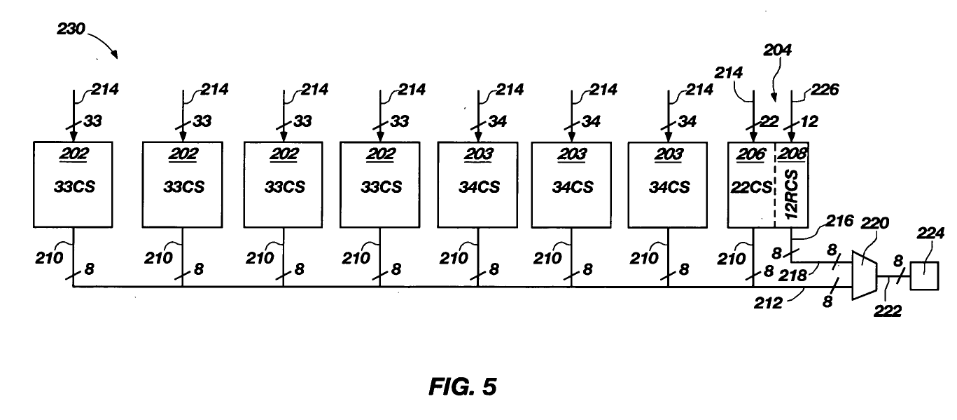

FIG. 5 is a block diagram of an embodiment of specific partitioning of a memory area 230. By way of example and not limitation, the normally used memory is accessible by two hundred fifty-six CS signals; however, in the present example, a lesser quantity of redundant memory cells are provided, such as might be the case if it was determined that the same was adequate for the manufacturing yield of the memory device. In the present embodiment, the redundant memory is accessible by twelve RCS signals. When the sum of the quantity of CS signals for accessing the normally used memory and the quantity of RCS signals for accessing the redundant memory is not evenly divisible across, for example, eight sub-arrays, the difference in the quantity of CS signals and the combination of CS signals and RCS signals is minimized to preserve the benefits of more evenly sized sub-arrays. While an embodiment using a reduced quantity of redundant memory cells is illustrated, other embodiments may require a greater number of redundant memory cells.

As previously stated, the partitioning of normally used memory cells and redundant memory cells may be done to minimize the difference in quantity of column select CS signals and redundant column select RCS signals across the various sub-arrays. Accordingly, for example, the normally used memory may be partitioned into seven, for example, sub-arrays including (i) four sub-arrays 202 each including a group of normally used memory cells accessible according to thirty-three CS signals per sub-array and (ii) three sub-arrays 203 each including a group of normally used memory cells accessible by thirty-four CS signals per sub-array. An eighth, for example, differently sized, group 206 of normally used memory cells is also partitioned, wherein the groups of memory cells are accessible by twenty-two CS signals. In order to provide the redundancy capability described above, a redundant memory cell group 208 includes redundant memory cells accessible according to twelve, for example, RCS signals, are also provided. The normally used memory cell group 206 is combined with the redundant memory cell group 208 to form an eighth sub-array 204.

Each of the sub-arrays 202, 203 and the group 206 of the normally used memory cells couples via I/O lines 210 to a Local Input/Output (LIO) line 212 for reading or writing data to specific memory cells within one of the sub-arrays 202, 203 or the group 206 when a respective CS signal 214 is activated. Similarly, the group 208 of the redundant memory cells couples via redundant I/O lines 216 to a Redundant Local Input/Output (RLIO) line 218 (same line as line 216 in the present example) for reading or writing data to specific memory cells within the redundant memory cell group 208 when a respective RCS signal 226 is activated. The LIO lines 212 and RLIO lines 218 couple to logic 220 for selectively multiplexing data between LIO line 212 and a DQ 224 via an external I/O 222 when the normally used memory cells are selected. When the redundant memory cells are selected, the logic 220 selectively multiplexes data between RLIO line 218 and DQ 224 via the external 1/0 222.

Similar to the embodiment of FIG. 4, separation of the LIO lines and the RLIO lines are simplified because the addressing distance from the normally used memory space to the redundant memory space can be a single address. Furthermore, the normally used memory area is contiguous in a single group and the redundant memory cell group 208 are also contiguous in a single group resulting in an improved repair efficiency. Additionally, writing a stress test pattern to the memory area should be simplified because the boundary between the normally used memory cells and the redundant memory cells is a single memory address.

As stated, the word lines (not shown) that traverse the sub-arrays for activating the memory cells in the sub-arrays exhibit a load that is based on the quantity of memory cells coupled to the word line across the sub-array. Accordingly, the word lines that traverse sub-array 204, which includes the redundant memory cell group 208, exhibit a substantially equivalent word line load when compared with the word lines that traverse sub-arrays 202, 203 since each of the sub-arrays 202, 203, 204 are configured to have a nearly equivalent quantity of CS signals 214 or CS signals 214 combined with RCS signals 226. In the present example, the quantity of either thirty-three or thirty-four signals of either CS signals 214 or CS signals 214 and RCS signals 226 are illustrated for each of the sub-arrays 202, 203, 204. Since each of the sub-arrays 202, 203, 204 are nearly equivalent in size, the performance, namely the read and write access times for the word lines, will be substantially equivalent which is in contrast to the differing performance of the sub-array 114 having forty eight CS signals 124 and RCS signals 136 of FIG. 2.

Additionally, each of the sub-arrays 202, 203, 204 may be similarly designed as a nearly common sub-array since the sub-array 204 including the redundant memory cell group 208 includes nearly the same quantity of CS signals (CS signals 214 and RCS signals 226) as the CS signals 214 of sub-arrays 202, 203. Accordingly, design and process defects should be more closely uniform across the entire memory area of a memory device.

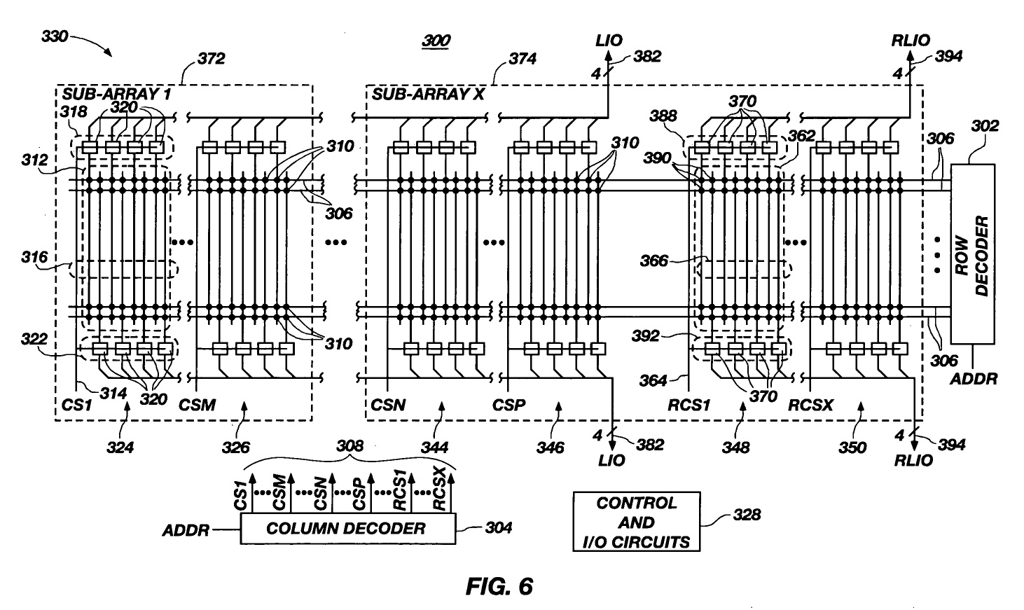

FIG. 6 is a partial block diagram of a memory device, in accordance with an embodiment of the present invention. A memory device 300 includes a memory area 330, row decoder 302 and column decoder 304. Memory device 300 further includes other control and I/O circuits 328 which may include command/mode registers, latches and counters not individually illustrated for brevity. Control and I/O circuits 328 may further include logic 130 (FIG. 2), 160 (FIG. 3), 190 (FIG. 4) and 220 (FIG. 5) for buffering and selecting between the LIO lines, RLIO lines and CLIO lines for connecting to DQ 134, 164, 194 and 224, respectively.

Row decoder 302 is employed to decode an address ADDR and activate a specific one of word lines 306 during either a read or write operation to the memory area. Column decoder 304 is also employed to decode an address ADDR and generate a column select CS signal during a read or write operation to the memory area. For simplicity of explanation, column decoder 304 is also illustrated as operable to generate redundant column select RCS signals 308. The various approaches and associated circuitry for storing addresses of identifiers designating defective memory cells and the methods for utilizing redundant memory cells are known by those of ordinary skill in the art and are not further described herein.

Memory area 330 include various sub-arrays 372, 374 as partitioned according to one of the various embodiments previously described with reference to FIGS. 2-5. Sub-array 372 is illustrated to include only normally used memory cells illustrated as one or more groups 324, 326 while sub-array 374 includes one or more groups 344, 346 of normally used memory cells as well as one or more groups 348, 350 of redundant memory cells. For brevity, only a single sub-array 372 of only normally used memory cells is illustrated; however, as previously described, a plurality of sub-arrays 112, 172, 202 including only normally used memory cells may be used in some embodiments, such as those illustrated with respect to FIGS. 2, 4 and 5.

Sub-array 372 includes a plurality of normally used memory cells 310 that are accessible by respective ones of word lines 306. Memory cells 310 are further selected by addresses ADDR that are partially decoded by column decoder 304. The column decoder 304 generates column select CS or redundant column select RCS signals 308 which individually activate or enable groups of memory cells 310. For example, in sub-array 372, a group 312 of normally used memory cells 310 is made accessible by activation of a column select CS signal 314. The memory cells 310, when activated by a respective one of word lines 306, output data along bit lines 316. By way of example and not limitation, bit lines 316 are illustrated according to an open-digit line architecture wherein a portion 318 of sense amplifiers 320 are located on one side of the array of memory cells 310 and another portion 322 of sense amplifiers 320 are located on an opposing side of the array of memory cells 310.

Accordingly, the memory area 330 is divided into a plurality of sub-arrays, two of which are illustrated as sub-arrays 372, 374 with each including groups of memory cells that are individually accessible by a decoded address signal, such as a column select CS signal or redundant column select RCS signal 308. The inclusion of a specific quantity of groups 324, 326 in a sub-array is illustrated with respect to the illustrations of FIGS. 2, 4 and 5 where between thirty-two and thirty-four groups 324, 326 are included in each sub-array 112, 172, 202, 203, although other quantities can be used in other embodiments.

During a read or write operation, a specific column select CS signal, such as column select CS signal 314, enables the sense amplifiers 320 associated with a group 324 of memory cells 310 allowing data to be read from or written to memory cells 310 that are activated by a specific word line 306. The data is exchanged with the activated sense amplifiers 320 along Local I/O (LIO) lines 382 which are commonly bussed along each of the sub-arrays 372, 374 which include normally used memory cells. By way of example, upper LIO lines 382 couple to the portion 318 of sense amplifiers 320 and lower LIO lines 382 couple to the portion 322 of sense amplifiers 320. The separation of upper and lower LIO lines 382 is a result of the illustrated open bit line architecture and is not to be considered as limiting.

As illustrated above with respect to FIGS. 2-5, at least a portion of the sub-arrays include redundant memory cells. In FIG. 6, sub-array 374 is illustrated to include groups 344, 346 of normally used memory cells as well as groups 348, 350 of redundant memory cells. A single sub-array 374 including normally used memory cells and redundant memory cells is illustrated as an example of sub-arrays 114, 144, 174, 204 as illustrated with respect to FIGS. 2-5.

Sub-array 374 includes a plurality of normally used memory cells 310 that are accessible by respective ones of word lines 306. Memory cells 310 are further selected by addresses ADDR that are partially decoded by column decoder 304. The column decoder 304 generates column select CS and/or redundant column select RCS signals 308 which individually activate or enable groups of memory cells 310. In sub-array 374, the groups 344, 346 of normally used memory cells 310 are configured, selected and operated as described above with reference to groups 324, 326 of the normally used memory cells.

Groups 348, 350 of redundant memory cells 390 are also accessible by respective ones of word lines 306. Redundant memory cells 390 are further selected by addresses ADDR that are partially decoded by column decoder 304. The column decoder 304 generates redundant column select RCS signals which individually activate or enable groups 348, 350 of redundant memory cells 390. For example, the group 362 of redundant memory cells 390 is made accessible by activation of a redundant column select RCS signal 364. The memory cells 390, when activated by a respective one of word lines 306, output data along bit lines 366. By way of example and not limitation, bit lines 366 are illustrated according to an open-digit line architecture wherein a portion 388 of sense amplifiers 370 are located on one side of the array of memory cells 390 and another portion 392 of sense amplifiers 370 are located on an opposing side of the array of memory cells 390.

As stated, the memory area 330 includes sub-array 374 including groups 344, 346, 348 and 350 that are individually accessible by a decoded address signal designated as a column select CS signal or a redundant column select RCS signal 308. The inclusion of a specific quantity of groups 348, 350 in sub-array 374 is illustrated with respect to the illustrations of FIGS. 2, 4 and 5 where between sixteen and twelve groups 348, 350 are included in each sub-array 114, 174, 204 and the illustration of FIG. 3 where two groups 348, 350 are included in each sub-array 144, although different quantities may be used with different embodiments.

During a read or write operation with redundancy memory cells selected, a specific redundant column select RCS signal, such as redundant column select RCS signal 364, enables the sense amplifiers 370 associated with a group 348 of redundant memory cells 390 allowing data to be read from or written to redundant memory cells 390 that are activated by a specific word line 306. The data is exchanged with the activated sense amplifiers 370 along Redundant Local I/O (RLIO) lines 394 which are commonly bussed along each of the groups 348, 350 in sub-array 374. By way of example, upper RLIO lines 394 couple to the portion 388 of sense amplifiers 370 and lower RLIO lines 394 couple to the portion 392 of sense amplifiers 370. The separation of upper and lower RLIO lines 394 is a result of the illustrated open bit line architecture and is not to be considered as limiting.

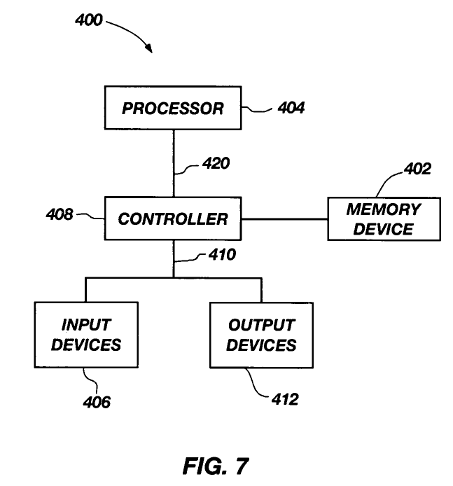

FIG. 7 is a block diagram of an electronic system. Electronic system 400 includes one or more memory devices 402 implemented according to one of the various embodiments described above and may comprise, by way of nonlimiting example, a personal computer, a server, a controller, a personal communication device, a digital camera, or other system including a processor operable in conjunction with at least one memory device 402. Electronic system 400 further includes a processor 404 for performing various functions, such as performing specific calculations or tasks. In addition, the electronic system 400 includes one or more input devices 406, such as a keyboard or a mouse, coupled to the processor 404 through a system controller 408 and a system bus 410. Typically, the electronic system 400 also includes one or more output devices 412 coupled to the processor 404, such output devices typically being a printer or a video terminal. The memory device 402 may also be coupled directly (not shown) to the processor 404 via a processor bus 420 or to the system controller 408 to allow data to be written to and read from the memory device 402.

The processes and devices described above illustrate methods and devices out of many that are contemplated according to the embodiments of the present invention. The above description and drawings illustrate embodiments illustrative of certain features and advantages of the present invention. It is not intended, however, that the present invention be strictly limited to the above-described and illustrated embodiments.

Although the present invention has been shown and described with reference to particular embodiments, various additions, deletions and modifications that will be apparent to a person of ordinary skill in the art to which the invention pertains, even if not shown or specifically described herein, are deemed to lie within the scope of the invention as encompassed by the following claims.

What is claimed is:

1. A method for partitioning a memory area, comprising:
aggregating selectable groups of normally used memory cells and redundant memory cells; and
partitioning a substantially equal quantity of the selectable groups into each of a plurality of sub-arrays with each of the selectable groups of the redundant memory cells being allocated to one of the plurality of sub-arrays.

2. The method of claim 1, further comprising structuring the selectable groups of the normally used memory cells to be individually selectable based on column select (CS) signals.

3. The method of claim 1, further comprising structuring the selectable groups of the redundant memory cells to be individually selectable based on redundant column select (RCS) signals.

4. The method of claim 1, wherein partitioning comprises partitioning an equal quantity of the selectable groups into each of a plurality of sub-arrays with each of the selectable groups of the redundant memory cells being allocated to one of the plurality of sub-arrays.

5. The method of claim 1, wherein partitioning comprises partitioning a first portion of the plurality of sub-arrays to include a first quantity of selectable groups and a second portion of the plurality of sub-arrays to include a second quantity of selectable groups differing from the first quantity of selectable groups by one.

6. The method of claim 1, further comprising bussing together inputs/outputs of each of the selectable groups of the normally used memory cells.

7. The method of claim 1, further comprising bussing together inputs/outputs of each of the selectable groups of the redundant memory cells.

8. A method for forming a memory area including a plurality of sub-arrays, the method comprising:
forming a plurality of normally used memory cell sub-arrays each including a substantially equal quantity of selectable groups of normally used memory cells; and
forming another sub-array including a quantity of selectable groups of normally used memory cells and all of the selectable groups of redundant memory cells, wherein each of the plurality of normally used memory cell sub-arrays and the another sub-array include substantially equal quantities of selectable groups.

9. The method of claim 8, further comprising:
generating column select (CS) signals for selecting the selectable groups of the normally used memory cells; and
generating redundant column select (RCS) signals for selecting the selectable groups of the redundant memory cells.

10. The method of claim 8, further comprising configuring each of the plurality of normally used memory cell sub-arrays and the another sub-array to each include an equal quantity of selectable groups.

11. The method of claim 8, further comprising configuring each of the plurality of normally used memory cell sub-arrays to include a quantity of selectable groups and the another sub-array to include a quantity of selectable groups differing from the quantity of selectable groups of the plurality of normally used sub-arrays by only one selectable group.

12. The method of claim 8, further comprising bussing together inputs/outputs of each of the selectable groups of the normally used memory cells.

13. The method of claim 8, further comprising bussing together inputs/outputs of each of the selectable groups of the redundant memory cells.

14. A memory device, comprising:
a plurality of normally used memory cell sub-arrays each including a substantially equal quantity of selectable groups of normally used memory cells; and
another sub-array including a quantity of selectable groups of normally used memory cells and all of the selectable groups of redundant memory cells, wherein each of the plurality of normally used memory cell sub-arrays and the another sub-array include substantially equal quantities of selectable groups.

15. The memory device of claim 14, wherein the selectable groups of the normally used memory cells are individually selectable based on column select (CS) signals.

16. The memory device of claim 14, wherein the selectable groups of the redundant memory cells are individually selectable based on redundant column select (RCS) signals.

17. The memory device of claim 14, wherein each of the plurality of normally used memory cell sub-arrays and the another sub-array each include an equal quantity of the selectable groups.

18. The method of claim 14, wherein each of the plurality of normally used memory cell sub-arrays includes a quantity of selectable groups and the another sub-array includes a quantity of selectable groups differing by one in quantity from the quantity of the selectable groups of the normally used memory cell sub-arrays.

19. A memory device, including:
a plurality of substantially equally sized sub-arrays of normally used memory cells and redundant memory cells, wherein groups of memory cells in a first portion of the sub-arrays are each selectable by a first quantity of select signals and a second portion of the sub-arrays are each selectable by a second quantity of select signals; and
wherein one of the plurality of sub-arrays partially includes all of the groups of the redundant memory cells selectable by respective redundant select signals.

20. The memory device of claim 19, wherein the first quantity of select signals and the second quantity of select signals are equal.

21. The memory device of claim 19, wherein the first quantity of select signals and the second quantity of select signals differ by one select signal.

22. The memory device of claim 19, wherein the selectable groups of the normally used memory cells are individually selectable based on column select (CS) signals.

23. The memory device of claim 19, wherein the selectable groups of the redundant memory cells are individually selectable based on redundant column select (RCS) signals.

24. An electronic system, comprising:
a processor; and
a memory device coupled to the processor, the memory device including a plurality of sub-arrays including groups of selectable normally used memory cells and groups of selectable redundant memory cells, wherein each of the plurality of sub-arrays includes a substantially equal quantity of groups and all of the groups of selectable redundant memory cells are resident in one of the plurality of sub-arrays.

25. The electronic system of claim 24, wherein the quantity of groups in each of the sub-arrays is equal.

26. The electronic system of claim 24, wherein the quantity of groups in each of the plurality of sub-arrays varies by only one group from any quantity of groups in any other one of the plurality of sub-arrays.

27. The electronic system of claim 24, wherein the selectable groups of the normally used memory cells are individually selectable based on column select (CS) signals.

28. The electronic system of claim 24, wherein the selectable groups of the redundant memory cells are individually selectable based on redundant column select (RCS) signals.
